(19) United States
(12) Patent Application Publication
(10) Pub. No.: US 2026/0084955 A1
(43) Pub. Date: Mar. 26, 2026

(54) TRIAXIAL MICROELECTROMECHANICAL GYROSCOPE WITH IMPROVED PERFORMANCES

(71) Applicant: STMicroelectronics International N.V., Geneva (CH)

(72) Inventors: Patrick FEDELI, Senago (IT); Paola CARULLI, Milano (IT); Luca Giuseppe FALORNI, Limbiate (MB) (IT); Federico MORELLI, Milano (IT)

(73) Assignee: STMicroelectronics International N.V., Geneva (CH)

(21) Appl. No.: 19/333,812

(22) Filed: Sep. 19, 2025

(30) Foreign Application Priority Data
Sep. 25, 2024 (IT) 102024000021338

(51) Int. Cl. B81B 3/00; G01C 19/5712; G01C 19/5733

(52) U.S. Cl. CPC B81B 3/0062; G01C 19/5712; G01C 19/5733; B81B 2201/0242; B81B 2203/0163; B81B 2203/0307; B81B 2203/04; B81B 2203/051; B81B 2203/056; B81B 2203/058

(57) ABSTRACT

A MEMS gyroscope has a structure with a main extension in a horizontal plane formed by first and second horizontal axes. The gyroscope includes a first driving mass that performs a translation driving movement along the second horizontal axis of the horizontal plane, and a first sensing mass, having an anchoring element arranged centrally with respect to the first sensing mass and connected to the anchoring element by an elastic arrangement. The first sensing mass is coupled to the first driving mass by an elastic coupling element and performs a rotation movement in the horizontal plane around the anchoring element, dragged by the first driving mass, and a sensing movement of rotation outside the horizontal plane around a rotation axis defined by the elastic arrangement, in response to an angular velocity around the first horizontal axis. The rotation axis extends along the second horizontal axis, parallel to the driving movement.

### PRIORITY CLAIM

This application claims the priority benefit of Italian Application for Patent No. 102024000021338 filed on Sep. 25, 2024, the content of which is hereby incorporated by reference in its entirety to the maximum extent allowable by law.

### TECHNICAL FIELD

This disclosure relates to a microelectromechanical gyroscope with improved performance; in particular, the following discussion will refer to a triaxial gyroscope, capable of sensing angular velocities acting along three orthogonal axes (typically denoted as roll, pitch, and yaw axes).

### BACKGROUND

As is known, current micromanufacturing techniques allow for the provision of microelectromechanical systems (so-called MEMS, “Micro Electro Mechanical System”) from layers of semiconductor material, which have been deposited (for example, a polycrystalline silicon layer) or grown (for example, an epitaxial layer) above sacrificial layers, which are removed by chemical etching.

Inertial sensors, accelerometers and gyroscopes provided with this technology are having increasing success, for example in the automotive field, in inertial navigation, or in the field of portable devices for high-end consumer electronics, for example for Optical Image Stabilization (OIS) purposes.

In particular, microelectromechanical gyroscopes made using MEMS technology from semiconductor materials (hereinafter simply referred to as MEMS gyroscopes) are known.

These MEMS gyroscopes operate on the basis of the relative acceleration theorem, exploiting the Coriolis acceleration. When a rotation at a certain angular velocity (the value of which is to be sensed) is applied to a mobile mass that is driven with a linear velocity, the mobile mass is subject to an apparent force, called the Coriolis force, which causes it to displace in a direction perpendicular to the direction of the driving linear velocity component and also perpendicular to the axis around which the rotation occurs. The mobile mass is supported by elastic elements that allow both the driving displacement and a sensing displacement in the direction of the fictitious force. According to Hooke's law, the displacement is proportional to the apparent force, so that, from the sensing displacement of the mobile mass, the Coriolis force and the value of the angular velocity of the rotation that generated it may be detected.

The sensing displacement of the mobile mass may, for example, be sensed capacitively. The sensing displacement of the mobile mass may, for example, be sensed capacitively, by determining, in resonance conditions, the capacitance variations caused by the movement of mobile sensing electrodes, integral with the mobile mass (or formed by parts of the same mobile mass) and coupled (for example, in a so-called “parallel-plate” configuration, or in an interdigitated configuration) to fixed or stator sensing electrodes.

In particular, known MEMS gyroscopes generally include, as schematically illustrated in FIG. 1A and FIG. 1B, a microelectromechanical structure having at least one driving mass 2 (for example, having a frame-like rectangular shape) that has a translational driving movement in a horizontal plane xy (which corresponds to a main extension plane of the same driving mass), for example, along a horizontal axis y, as indicated by the arrow in FIG. 1A.

At least one sensing mass 4 is coupled to this driving mass 2 and is provided with an anchoring structure 5 for anchoring to a corresponding substrate (not illustrated here), arranged centrally with respect to the sensing mass 4.

The sensing mass 4 is rigidly coupled to the driving mass in the driving movement, so as to perform a rotation movement in the horizontal plane xy around the anchoring structure 5 (as indicated by the rotation arrow); this movement involves, in particular, a linear motion component along a horizontal axis x at end portions of the sensing mass 4 (again, as indicated by the arrows in the aforementioned FIG. 1A).

As shown in FIG. 1B, due to the Coriolis force, the sensing mass 4 is therefore capable of performing a sensing movement, which corresponds to a rotation outside the horizontal plane xy, around a rotation axis A, arranged in a central position, in the example, parallel to the horizontal axis x.

It has been demonstrated that this arrangement of the sensing mass 4, which rotates around a central anchor, is advantageous with respect to robustness to disturbance vibrations.

The coupling of the driving mass 2 to the sensing mass 4 is generally provided, in known solutions, by a single elastic coupling element (or “spring”) 6, having a linear extension, interposed between the driving and sensing masses 2, 4 in a central position, at the rotation axis A and lying along the same rotation axis A.

In particular, this elastic coupling element 6 couples the driving movement (of the translational type) to the sensing movement (of the rotational type), as previously described.

Although it is certainly an efficient and advantageous solution, the previously described coupling mechanism may nevertheless have some issues.

In particular, in this solution, the direction of the driving movement has to be perpendicular to the rotation axis A (around which the sensing movement of rotation outside the horizontal plane xy occurs).

The design of the microelectromechanical structure of the MEMS gyroscope is therefore constrained by the presence of such relative movement between the driving and sensing masses.

Also, due to the fact that the aforementioned elastic coupling mechanism significantly impacts the characteristics and performance of the gyroscope, for example, in terms of area occupation, detection sensitivity, and frequencies of the operating modes, it would be advantageous to have a more flexible solution in terms of design and mutual positioning of the driving and sensing masses.

In general, a need is currently felt for a MEMS gyroscope, in particular of the triaxial type, having reduced area occupation and reduced power consumptions and that also provides improved rejection of vibrations, which represent a disturbance with respect to the sensing of angular velocities of interest. Recently developed and widespread applications require, in fact, more demanding specifications for the rejection of vibrations and, concurrently, the maintenance of sizes and performance comparable to those of known sensors, to maintain full compatibility with current consumer products.

The aforementioned MEMS gyroscopes are also required to have high performance regarding the accuracy of the sensitivity value, for which it is particularly important to ensure reduced interference values between the sensing axes (so-called “cross-axis” interference).

However, currently known gyroscope structures, also due to the design constraints previously discussed, do not always allow the desired performance to be achieved.

There is a need to overcome the limitations of known devices and to provide an answer to the aforementioned need.

### SUMMARY

According to the present solution, a microelectromechanical (MEMS) gyroscope, in particular of the triaxial type, is therefore provided.

For example, a MEMS gyroscope includes a microelectromechanical structure having a main extension in a horizontal plane formed by a first horizontal axis and a second horizontal axis. The structure includes a first driving mass configured to perform a translation driving movement along the second horizontal axis of the horizontal plane and a first sensing mass having an anchoring element arranged centrally with respect to the first sensing mass and connected to the anchoring element by an elastic arrangement. The first sensing mass is coupled to the first driving mass by an elastic coupling element and is configured to perform a rotation movement in the horizontal plane around the anchoring element, dragged by the first driving mass, and a sensing movement of rotation outside the horizontal plane around a rotation axis defined by the elastic arrangement, in response to a first angular velocity around the first horizontal axis. The rotation axis extends along the second horizontal axis, parallel to the translation driving movement of the first driving mass.

The elastic coupling element may include a central portion linear along a direction of the second horizontal axis, rigid so as to transfer the translation driving movement of the first driving mass to the first sensing mass, and end portions arranged at distal ends of the central portion, respectively coupled to the first driving mass and to the first sensing mass. The end portions may be elastic and yielding to allow rotation outside the horizontal plane of the first sensing mass.

The first sensing mass may have an extension along the first horizontal axis, symmetrical with respect to the rotation axis, and the elastic coupling element may be coupled to the first sensing mass at a coupling point arranged at a distance that is non-zero from the rotation axis along the first horizontal axis.

The central portion of the elastic coupling element may have a length along the second horizontal axis and the end portions of the elastic coupling element may have a folded shape, with an overall extension along the first horizontal axis and with a thickness of branches forming the folded shape. A value of the distance may determine a detection sensitivity of the first sensing mass and a value of the length of the central portion and of the overall extension and of the thickness of the end portions may determine a frequency of the sensing movement. The first sensing mass may have a central window, within which the anchoring element is arranged, in a central position. The elastic arrangement may also be arranged in the central window, having a main extension along the second horizontal axis and defining the rotation axis.

The microelectromechanical structure may have a first axis of symmetry and a second axis of symmetry, extending respectively along the first horizontal axis and along the second horizontal axis. The structure may include, in addition to the first driving mass, a second driving mass to thereby form a first pair of driving masses arranged on a same side of the second axis of symmetry, aligned along the second horizontal axis, and a third driving mass and a fourth driving mass that form a second pair of driving masses arranged in a symmetrical manner to the driving masses of the first pair with respect to the second axis of symmetry and aligned along the second horizontal axis. The structure may include, in addition to the first sensing mass that represents a first pitch sensing mass for sensing a pitch angular velocity around the first horizontal axis, a second pitch sensing mass to form a pair of pitch sensing masses arranged in a symmetrical manner with respect to the first axis of symmetry, externally with respect to all of the driving masses of the first pair and of the second pair. The first pitch sensing mass may be elastically coupled also to the third driving mass through a respective elastic coupling element having features corresponding to the elastic coupling element, and the second pitch sensing mass may be elastically coupled to both the second driving mass and the fourth driving mass through respective elastic coupling elements having features corresponding to the elastic coupling element. The structure may include a first roll sensing mass and a second roll sensing mass for sensing a roll angular velocity around the second horizontal axis, arranged symmetrically to each other on opposite sides of the first axis of symmetry and elastically connected to each other by an elastic coupling element arranged centrally at the second axis of symmetry. The first roll sensing mass and second roll sensing mass may be arranged internally with respect to all of the driving masses of the first and second pairs, and the first roll sensing mass may be elastically coupled to the first and third driving masses by respective elastic coupling elements aligned along the first horizontal axis and the second roll sensing mass may be elastically coupled to the second and fourth driving masses by respective elastic coupling elements aligned along the first horizontal axis. The structure may include a first pair of yaw sensing masses and a second pair of yaw sensing masses for sensing a yaw angular velocity around a vertical axis orthogonal to the horizontal plane, arranged externally and coupled to the first and second pairs of driving masses by respective elastic coupling elements. The pitch sensing masses, the first roll sensing mass, the second roll sensing mass, the first pair of yaw sensing masses, and the second pair of yaw sensing masses may be driven by all of the driving masses of the first and second pairs, with a common driving mode, in order to perform the respective sensing movements for detection of the pitch, roll and yaw angular velocities.

The first, second, third, and fourth driving masses may be configured to perform a translation movement, in phase-opposition for each pair, along the second horizontal axis, the translation movement of the first, second, third, and fourth driving masses symmetrical to each other with respect to the first axis of symmetry also being in phase-opposition. The translation movement of the driving masses may be configured to cause a rotation in phase-opposition of the first roll sensing mass and the second roll sensing mass in the horizontal plane, around an axis parallel to the vertical axis and passing through a respective center of the first roll sensing mass and the second roll sensing mass, a translation movement in phase-opposition along the second horizontal axis of the first pair of yaw sensing masses and second pair of yaw sensing masses in a manner integral with the first, second, third, and fourth driving masses, and a rotation in phase-opposition of the pitch sensing masses around an axis parallel to the vertical axis and passing through a respective center of the pitch sensing masses.

Movements of the first roll sensing mass, second roll sensing mass, first pair of yaw sensing masses, second pair of yaw sensing masses, and pitch sensing masses due to the translation movement of the first, second, third, and fourth driving masses may occur entirely in the horizontal plane.

The sensing movements of the first roll sensing mass, second roll sensing mass, first pair of yaw sensing masses, second pair of yaw sensing masses, and pitch sensing masses may be independent of each other and do not have any mutual influences.

The first, second, third, and fourth driving masses may operate as decoupling elements between the first roll sensing mass, the second roll sensing mass, the first pair of yaw sensing masses, the second pair of yaw sensing masses, and the pitch sensing masses, which are all connected to the first driving mass, without mutual connections.

The pitch sensing masses may be configured to perform, in presence of the pitch angular velocity around the first horizontal axis and due to Coriolis force, respective rotation movements outside the horizontal plane, in phase-opposition with each other, around the respective rotation axis defined by a respective elastic arrangement for coupling to a respective anchoring element.

The first roll sensing mass and the second roll sensing mass may be configured to perform, in presence of the roll angular velocity around the second horizontal axis and due to Coriolis force, a rotation in phase-opposition outside the horizontal plane around a respective rotation axis defined by corresponding elastic coupling elements.

The first pair of yaw sensing masses, the second pair of yaw sensing masses, in presence of a yaw angular velocity around the vertical axis and due to Coriolis force, may be configured to carry out a translation movement in phase-opposition along the first horizontal axis.

Each of the first roll sensing mass and the second roll sensing mass may have a substantially rectangular shape in the horizontal plane, elongated along the second horizontal axis and centrally has a window, inside of which a respective roll anchor is arranged, to which it is coupled by an elastic coupling arrangement defining a rotation axis for the sensing movement outside the horizontal plane.

The yaw sensing masses and the first pair of yaw sensing masses and the yaw sensing masses of the second pair of yaw sensing masses may be coupled to each other by respective elastic coupling structures, which extend centrally along the second horizontal axis, traversing the first axis of symmetry. Each elastic coupling structure may define a lever elastic element, of a central fulcrum type, hinged at a central anchor and coupled at its ends to the respective yaw sensing masses of the first or the second pair.

### BRIEF DESCRIPTION OF THE DRAWINGS

For a better understanding of the present invention, a preferred embodiment thereof is now described, purely by way of non-limiting example and with reference to the attached drawings, wherein:

FIGS. 1A and 1B show a schematic plan view of a known microelectromechanical structure, with reference to a corresponding driving movement and, respectively, to a corresponding sensing movement;

FIG. 2A shows a schematic plan view of a portion of a microelectromechanical structure, in particular of a MEMS gyroscope, with reference to an elastic coupling structure between a driving mass and a sensing mass;

FIG. 2B shows an enlarged plan view of the elastic coupling structure of FIG. 2A, according to an aspect of the present solution;

FIG. 3 shows a schematic plan view of the microelectromechanical structure of a triaxial MEMS gyroscope, according to a further aspect of the present solution;

FIG. 4 schematically shows driving modes in the gyroscope of FIG. 3;

FIG. 5 schematically shows a pitch sensing mode in the gyroscope of FIG. 3;

FIG. 6 schematically shows a roll sensing mode in the gyroscope of FIG. 3; and

FIG. 7 schematically shows a yaw sensing mode in the gyroscope of FIG. 3.

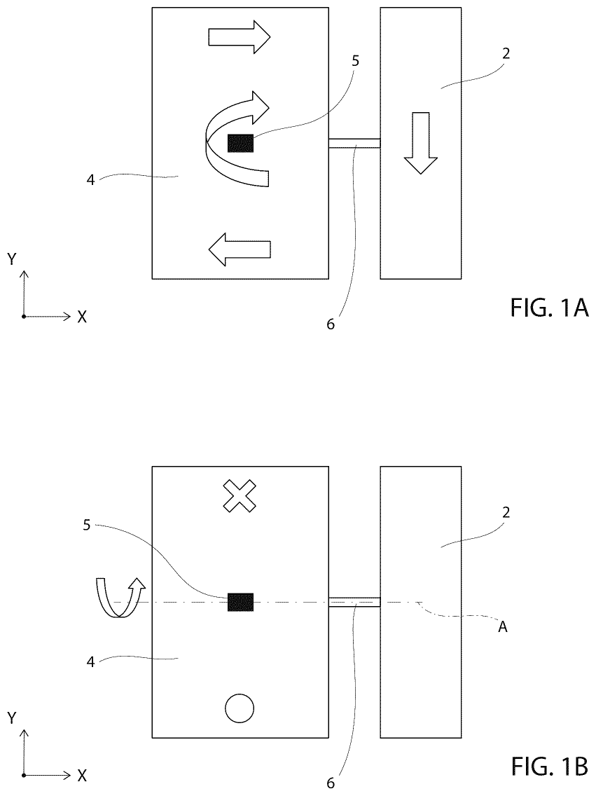

### DESCRIPTION OF EMBODIMENTS

As will be described below, a first aspect of the present solution provides an optimized elastic structure for the elastic coupling of a sensing mass to a corresponding driving mass in a MEMS gyroscope, in particular, of the triaxial type.

This elastic structure is configured to couple the translational driving movement of the driving mass into a rotation movement of the sensing mass in the horizontal plane (around a central anchor), thus allowing a sensing movement of rotation outside the same horizontal plane, in the presence of an angular velocity to be detected.

In particular, the elastic structure is configured so that the direction of the translational driving movement of the driving mass is parallel to the rotation axis around which the aforementioned sensing movement of rotation outside the horizontal plane of the sensing mass occurs.

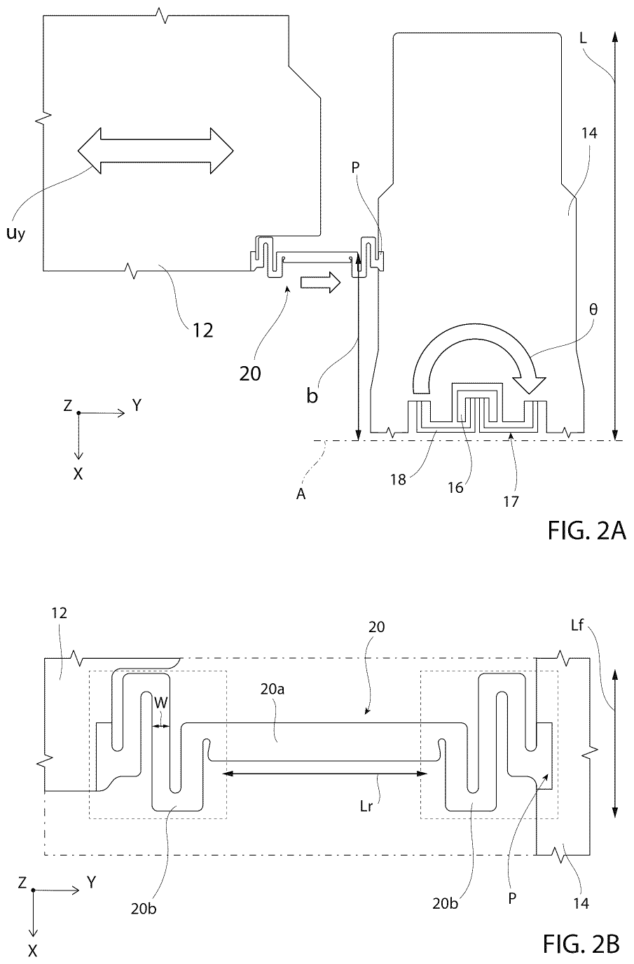

FIG. 2A shows a portion of a microelectromechanical structure of a MEMS gyroscope, for example, of the triaxial type, which includes at least one driving mass 12 and at least one sensing mass 14.

The sensing mass 14 (of which only a first half is shown in the aforementioned FIG. 2A) has, in the example, a generally rectangular shape elongated along a horizontal axis x of a horizontal plane xy, which coincides with a main extension plane of the first sensing mass 14 (which has a minor extension, substantially negligible compared to the aforementioned main extension, along a vertical axis z, orthogonal to the horizontal plane xy).

In particular, in FIG. 2A, the half-length of the sensing mass 14 along the horizontal axis x is denoted by L.

The sensing mass 14 is centrally coupled to an anchoring element 16, integral with a substrate (here not illustrated), which is arranged below the first sensing mass 14 and from which the microelectromechanical structure of the MEMS gyroscope is formed (this anchoring element 16 is, for example, formed by a vertical pillar that extends along the aforementioned vertical axis z until it reaches the underlying substrate).

In particular, the sensing mass 14 has a central window 17, having the aforementioned anchoring element 16 arranged therewithin, and is elastically connected to the same anchoring element 16 by an elastic arrangement 18, which has a main extension along the horizontal axis y of the aforementioned horizontal plane xy and defines a rotation axis A for the rotation outside the horizontal plane xy of the sensing mass 14.

The driving mass 12 (of which only a first half is shown in the aforementioned FIG. 2A) also has, in the example, a generally rectangular shape elongated along the horizontal axis y.

In particular, the sensing mass 14 is elastically coupled to the driving mass 12 through a coupling elastic element 20.

This coupling elastic element 20 has a generally elongated extension, in the example, along the horizontal axis y (i.e., parallel to the aforementioned rotation axis A) and is interposed between the sensing mass 14 and the driving mass 12, being, in particular, coupled to the sensing mass 14 at a coupling point P placed at a distance b from the rotation axis A, measured along the horizontal axis x; therefore, the relationship 0<b<L applies (the coupling point P may, evidently, correspond, for example, to a central point of an area of actual coupling between the aforementioned coupling elastic element 20 and the sensing mass 14).

In detail, as illustrated in FIG. 2B, according to an embodiment of the present solution, the coupling elastic element 20 comprises a linearly elongated central portion 20a with length Lr, in the example, along the direction of the horizontal axis y, that is rigid along the same direction in order to transfer the driving movement of the driving mass 12 to the sensing mass 14 (driving movement that occurs along the same direction of extension of the coupling elastic element 20, therefore, parallel to the rotation axis A).

The coupling elastic element 20 also comprises end portions 20b, arranged at the distal ends of the aforementioned central portion 20a, coupled to the driving mass 12 and, respectively, to the sensing mass 14.

These end portions 20b are elastic and yielding to movements outside the horizontal plane xy, so as to allow the rotation of the sensing mass 14 around the rotation axis A.

In detail, in the embodiment illustrated in FIG. 2B, the end portions 20b have a folded, bellows, or serpentine shape (with shorter parts extending linearly along the horizontal axis y that alternate with longer parts extending along the horizontal axis x, the latter having alternating opposite directions), with an overall extension along the horizontal axis x indicated by Lf; the branches forming the folded pattern also have substantially the same thickness, indicated by w.

As previously discussed, the configuration of the coupling elastic element 20 is such as to transfer, with limited area occupation, the translational driving movement of the driving mass 12 into the rotation movement of the sensing mass 14 in the horizontal plane xy (around the corresponding central anchor, defined by the anchoring element 16), thus allowing its out-of-plane sensing movement due to the Coriolis force in the presence of an angular velocity (for example, a pitch angular velocity around the horizontal axis x, as will be described in detail below).

In particular, as previously highlighted, the direction of the driving movement of the driving mass 12 is, in this solution, parallel to the rotation axis A around which the sensing movement of the sensing mass 14 occurs.

Furthermore, the configuration of the aforementioned coupling elastic element 20 is such as to easily allow adjustment of the sensitivity value in sensing the angular velocity, simply by appropriately adjusting the distance b from the rotation axis A of the coupling point P with the sensing mass 14.

In fact, the following relationship applies, that defines the transmission of motion between the driving mass 12 (translational movement) and the sensing mass 14 (rotational movement): where u_y indicates the displacement of the driving mass 12, in the example, along the horizontal axis y due to the aforementioned translational movement, and 0 indicates the rotation angle of the rotation movement in the horizontal plane xy performed by the sensing mass 14, around the anchoring element 16.

Furthermore, it is easy to adjust the value of the resonance frequency of the sensing mode by acting on the stiffness of the coupling elastic element 20, without significantly affecting the driving mode.

In particular, the stiffness of the coupling mechanism may be adjusted by acting on the values of the overall extension Lf and thickness w associated with the end portions 20b of the coupling elastic element 20 and also on the value of the length Lr of the central portion 20a of the same coupling elastic element 20.

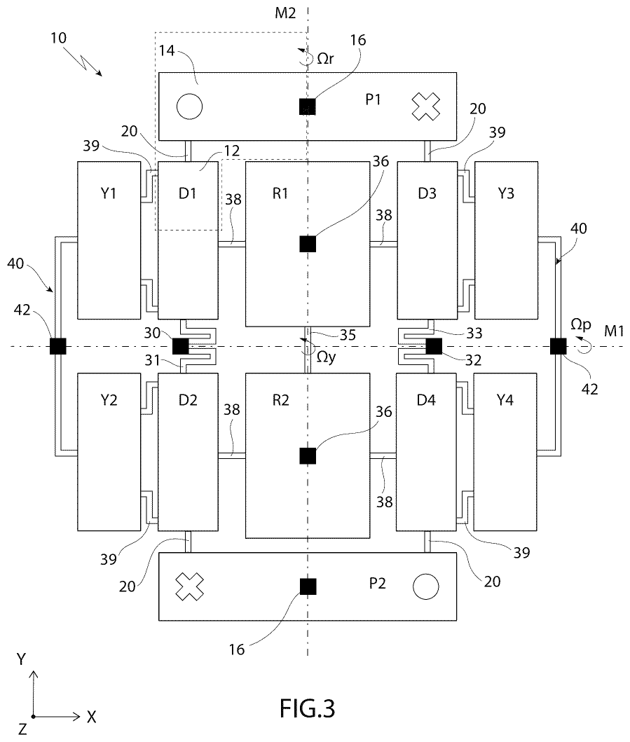

For example, a 10% modification in the aforementioned thickness w may result in a variation of about 5% in the resonance frequency associated with the sensing movement and a variation of less than 1% in the resonance frequency associated with the driving movement. With reference to FIG. 3, a possible embodiment of the microelectromechanical structure, here indicated by 10, of a triaxial MEMS gyroscope is now fully described, in accordance with a further aspect of the present solution, which comprises, inter alia, the aforementioned driving mass 12 and the aforementioned sensing mass 14 (in FIG. 3, a portion corresponding to the structure described with reference to FIG. 2 is highlighted in a dashed box).

As will be described in detail, this embodiment advantageously allows, with reduced area occupation, the reduction of interferences between the sensing axes and also the achievement of high performance in terms of rejection of disturbance vibrations.

The microelectromechanical structure 10 has a main extension in the horizontal plane xy (in a manner not illustrated, being suspended above a substrate at a certain separation distance along the vertical axis z) and first and second axes of symmetry (or median axes) M1, M2, extending respectively along the horizontal axis x and along the horizontal axis y.

The microelectromechanical structure 10, in addition to the aforementioned driving mass 12, which here represents a first driving mass indicated by D1, also comprises a second driving mass D2, to form a first pair of driving masses D1, D2, arranged on the same side of the second axis of symmetry M2, aligned along the horizontal axis y.

The driving masses of the first pair D1, D2 are also coupled, in the illustrated embodiment, to the same first driving anchor 30, integral with the substrate (in a manner not illustrated), arranged centrally at the first axis of symmetry M1, by a respective anchoring elastic element 31, of the folded or bellows type.

The microelectromechanical structure 10 also comprises third and fourth driving masses, indicated by D3 and D4, which form a second pair of driving masses.

The driving masses of the second pair D3, D4 are arranged on a second side of the second axis of symmetry M2, aligned along the horizontal axis y, in a manner symmetrical to the driving masses of the first pair D1, D2 with respect to the second axis of symmetry M2.

The driving masses of the second pair D3, D4 are, in this case, coupled to the same second driving anchor 32, integral with the substrate (in a manner not illustrated), arranged centrally at the first axis of symmetry M1, by a respective anchoring elastic element 33, of the folded or bellows type (again, in an entirely symmetrical manner with respect to the driving masses of the first pair D1, D2).

In a manner not illustrated in detail herein, the driving masses of the first and second pairs D1, D2, D3, D4 may internally define windows for mobile driving electrodes, integral with the same masses and interdigitated with corresponding fixed driving electrodes, also arranged within the same windows; in a known manner, the interaction between the interdigitated electrodes determines the aforementioned driving movement.

The microelectromechanical structure 10 of the MEMS gyroscope also comprises, in addition to the aforementioned sensing mass 14, which here is configured to sense a pitch angular velocity and is therefore referred to as a first pitch sensing mass P1, a second pitch sensing mass P2, to form a pair of pitch sensing masses P1, P2.

In particular, the pitch sensing masses P1, P2 are arranged in a symmetrical manner with respect to the first axis of symmetry M1, externally with respect to the driving masses D1, D2, D3, D4 (along the direction of the horizontal axis y) and extend longitudinally along the horizontal axis x, traversing the second axis of symmetry M2, symmetrically with respect to the second axis of symmetry M2.

The first pitch sensing mass P1 is elastically coupled to both the first driving mass D1 and the third driving mass D3 (i.e., to the driving masses arranged on the same side with respect to the first axis of symmetry M1) through a respective coupling elastic element 20, configured and operating in a manner entirely similar to what has been previously described.

Similarly, the second pitch sensing mass P2 is elastically coupled to both the second driving mass D2 and the fourth driving mass D4 through a respective coupling elastic element 20, again configured and operating in a manner entirely similar to what has been previously described.

The microelectromechanical structure 10 further comprises first and second roll sensing masses R1, R2, arranged symmetrically to each other on opposite sides of the first axis of symmetry M1 and elastically connected to each other by a coupling elastic element 35, arranged centrally at the second axis of symmetry M2 and having a stiffness such as to allow the motion of the roll sensing masses R1, R2 (as will be described in detail below) and, at the same time, such as to keep them constrained to each other in their movement.

The roll sensing masses R1, R2 are generally arranged in a central position within the driving masses of the first and second pairs D1, D2, D3, D4.

Each roll sensing mass R1, R2 has a substantially rectangular shape in the horizontal plane xy, in the example, elongated along the horizontal axis y and has centrally a window (not illustrated here for reasons of simplicity of illustration) having a respective roll anchor 36 arranged therewithin, to which it is coupled by an elastic coupling arrangement (not shown for simplicity of illustration) that defines a rotation axis (extending, in the example, along the horizontal axis x) for the sensing movement outside the horizontal plane xy.

This elastic coupling arrangement may, for example, be provided as described in detail in Italian Application for Patent No. 102024000017707 entitled “Microelectromechanical Structure With Improved Mechanical Robustness” by inventors: Patrick FEDELI, Paola CARULLI, Luca Giuseppe FALORNI, and Federico MORELLI, filed on Jul. 30, 2024 (incorporated herein by reference).

Furthermore, the first roll sensing mass R1 is elastically coupled to the first and third driving masses D1, D3, by respective elastic coupling elements 38, which extend from opposite sides of the first roll sensing mass R1, aligned along the horizontal axis x. As schematically shown in FIG. 3, such elastic coupling elements 38 may, for example, be of a linear type.

Similarly, the second roll sensing mass R2 is elastically coupled to the second and fourth driving masses D2, D4, by respective elastic coupling elements 38, which extend from opposite sides of the second roll sensing mass R2, generally along the horizontal axis x (being, for example, of a linear type).

Below the roll sensing masses R1, R2 (in a manner not illustrated here), respective fixed or stator electrodes are arranged, capacitively coupled to the respective roll sensing masses R1, R2 and placed above the substrate (so as to provide a differential sensing scheme, of a known type, not described in detail herein).

The microelectromechanical structure 10 of the MEMS gyroscope also comprises a first pair of yaw sensing masses Y1, Y2 and a second pair of yaw sensing masses Y3, Y4, each having a substantially rectangular shape in the horizontal plane, in the example, elongated along the horizontal axis y.

Each yaw sensing mass of the first pair Y1, Y2 is elastically coupled to a respective driving mass of the first pair of driving masses D1, D2 by respective coupling elastic elements 39 (in the example, in a number equal to two for each mass, interposed between end portions of the coupled driving and yaw sensing masses).

Similarly, each yaw sensing mass of the second pair Y3, Y4 is elastically coupled to a respective driving mass of the second pair of driving masses D3, D4 by respective coupling elastic elements 39.

Furthermore, the yaw sensing masses of the first pair Y1, Y2, and the yaw sensing masses of the second pair Y3, Y4, are respectively coupled to each other by respective elastic coupling structures 40, which extend centrally along the horizontal axis y, traversing the first axis of symmetry M1.

In detail, each elastic coupling structure 40 defines a lever elastic element, of the central fulcrum type, hinged to the substrate by a central anchor 42 and coupled at its ends to the respective yaw sensing masses that form the first or second pair.

In a manner not illustrated for reasons of simplicity of representation, the aforementioned yaw sensing masses Y1, Y2, Y3, Y4 have internal windows for yaw mobile sensing electrodes, integral with the same masses and alternating with corresponding yaw fixed or stator sensing electrodes, to define a differential sensing scheme.

Operation of the microelectromechanical structure 10 of the MEMS gyroscope is now described, for sensing a pitch angular velocity Ωp around the horizontal axis x, a roll angular velocity Ωr around the horizontal axis y, and a yaw angular velocity Ωy around the vertical axis z.

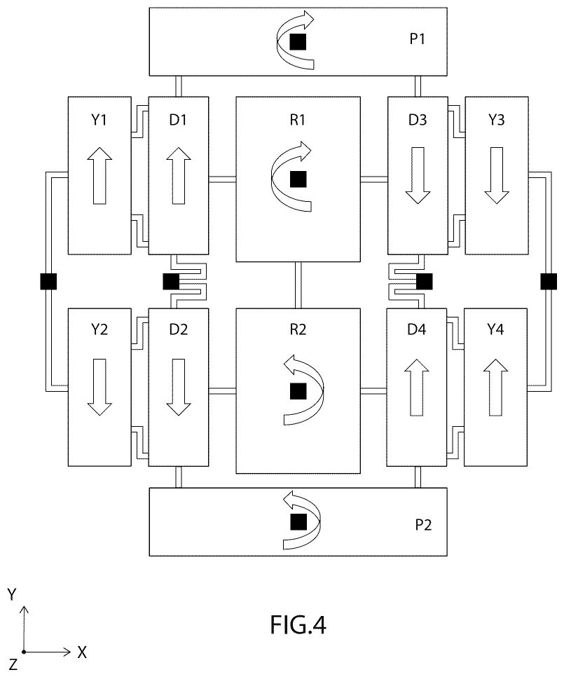

As schematically shown in FIG. 4, the driving movement involves the driving masses D1, D2, D3, D4 being driven (by the appropriate biasing of the mobile driving electrodes and the corresponding fixed driving electrodes) to perform a translational movement (in phase-opposition for each pair) along the horizontal axis y. Furthermore, the movement of the driving masses of each pair symmetrical to each other with respect to the first axis of symmetry M1 (i.e., of the driving masses D1, D3 and D2, D4), is also in phase-opposition.

As highlighted by the arrows in the aforementioned FIG. 4, the movement of the driving masses D1, D2, D3, D4 causes, due to the elastic couplings previously described, corresponding movements of the sensing masses.

In particular, the roll sensing masses R1, R2 are driven into a rotation in phase-opposition in the horizontal plane xy, around an axis parallel to the vertical axis z and passing through the center of the respective roll anchor 36.

Furthermore, the yaw sensing masses Y1, Y2, Y3, Y4 are driven by the associated driving masses D1, D2, D3, D4 in an integral manner in the same translational movement in phase-opposition along the horizontal axis y.

The movement of the driving masses D1, D2, D3, D4 also causes, due to the coupling elastic elements 20 (which operate as previously described in detail), a rotation in phase-opposition of the pitch sensing masses P1, P2, around an axis parallel to the vertical axis z and passing through the center of the respective anchoring element 16.

The aforementioned driving movements therefore occur entirely in the horizontal plane xy and do not affect further elements of the microelectromechanical structure 10 of the MEMS gyroscope.

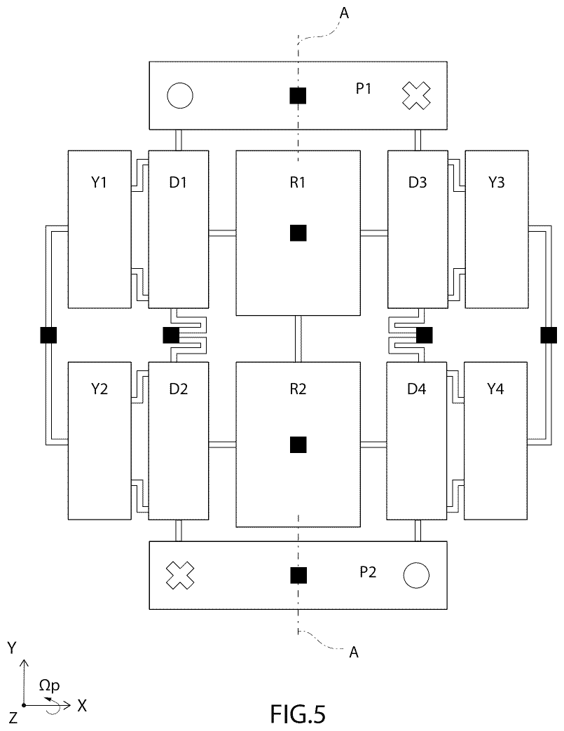

As schematically shown in FIG. 5 (corresponding to a given operating instant), in the presence of a pitch angular velocity Ωp around the horizontal axis x, the motion of the microelectromechanical structure 10 involves a rotation of the pitch sensing masses P1, P2 in phase-opposition outside the horizontal plane xy, around the rotation axis A, parallel to the horizontal axis y and defined by the respective elastic arrangement 18 (shown in FIG. 2A).

In essence, as schematically represented in FIG. 5, the pitch sensing masses P1, P2 perform, due to the Coriolis force, rotation movements outside the horizontal plane xy, in phase-opposition with each other, determining, along the vertical axis z, a movement away from/towards the respective pitch stator electrodes (not illustrated here), and, overall, a capacitive variation that may be detected by a differential sensing scheme.

It is emphasized that the other elements of the microelectromechanical structure 10 of the MEMS gyroscope (in particular, the masses and the associated elastic elements for sensing the roll and yaw angular velocities) are not substantially affected in this operating condition or, in any case, do not interfere with the operating mode of detection of the pitch angular velocity.

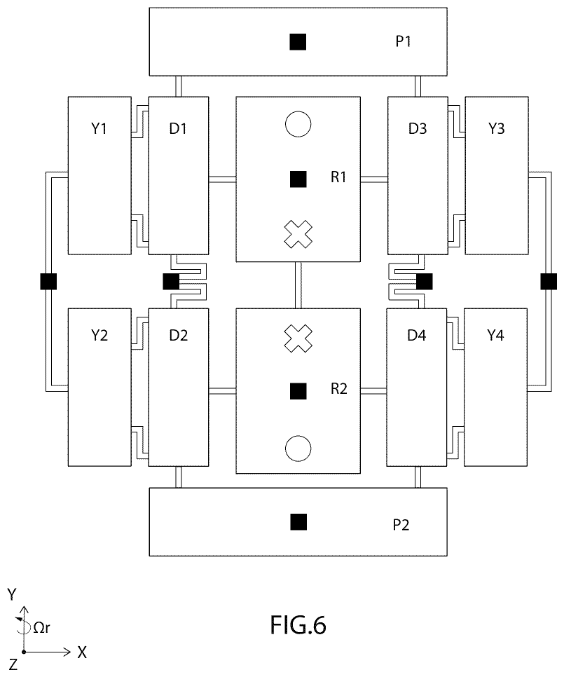

As schematically shown in FIG. 6 (corresponding to a given operating instant), in the presence of a roll angular velocity Ωr around the horizontal axis y, the motion of the microelectromechanical structure 10 involves a rotation in phase-opposition outside the horizontal plane xy of the roll sensing masses R1, R2 around the rotation axis defined by the corresponding elastic coupling elements (that, again, can be detected by a differential sensing scheme and respective sensing electrodes, not illustrated here).

Also in this case, the other elements of the microelectromechanical structure 10 (in particular, those used to sense the pitch and yaw angular velocities) are not substantially affected in this operating condition or, in any case, do not interfere with the roll sensing movement.

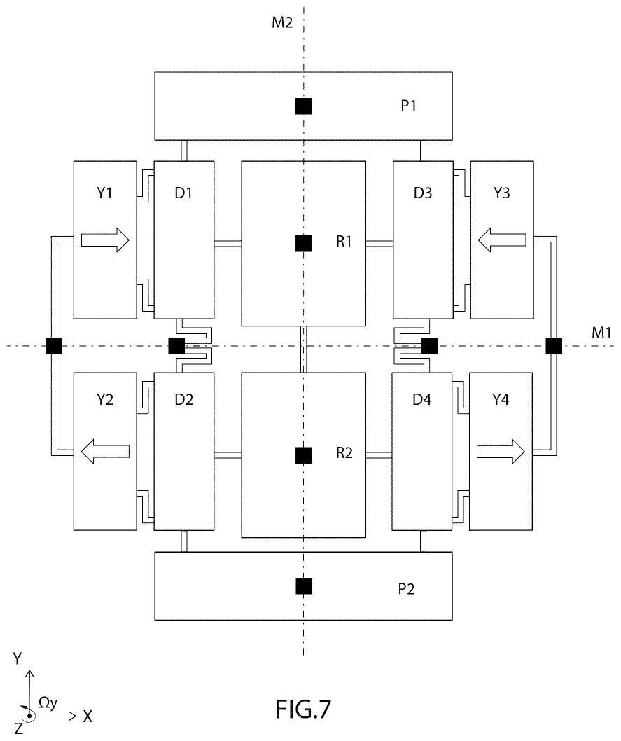

As schematically shown in FIG. 7, in the presence of a yaw angular velocity Ωy around the vertical axis z, the sensing motion of the microelectromechanical structure 10 of the MEMS gyroscope involves a displacement in phase-opposition of the yaw sensing masses Y1, Y2, Y3, Y4 of each pair along the horizontal axis x (as indicated by the arrows). Furthermore, the movement of the yaw sensing masses of each pair symmetrical to each other with respect to the second axis of symmetry M2 (i.e., of the yaw sensing masses Y1, Y3 and Y2, Y4), is also in phase-opposition.

This movement also causes rotation in the horizontal plane xy around the respective central anchor 42 of the lever elastic elements of the elastic coupling structures 40 that couple to each other the yaw sensing masses symmetrical with respect to the horizontal axis x.

A movement of yaw mobile electrodes (not illustrated here) along the horizontal axis x, with respect to alternating yaw stator electrodes, and a consequent capacitive variation that may be sensed by the differential scheme, thus occur.

Again, the other elements of the microelectromechanical structure 10 (in particular, those used to sense the pitch and roll angular velocities) remain substantially stationary in this operating condition or, in any case, do not interfere with sensing of the yaw movement.

Advantageously, the sensing movements of the yaw, roll, and pitch sensing masses are therefore entirely independent of each other and do not have any mutual influences, effectively making the interference between the sensing axes of the MEMS gyroscope (so-called cross-axis interference) substantially zero or, in any case, negligible.

In particular, the driving masses D1-D4 substantially operate as decoupling elements between the various sensing masses, which are, in fact, all connected to only the driving masses D1-D4, essentially without mutual connections (and interferences), and are driven by the same driving masses D1-D4 with a single driving mode.

Furthermore, the adopted differential sensing scheme allows the effects related to both linear and angular disturbance vibrations to be eliminated.

In particular, all the operating modes (i.e., the driving modes and the sensing modes) are not excitable by linear or rotational accelerations; furthermore, no spurious mode within a wide frequency range (e.g., up to 40 kHz) may be excited by a linear acceleration.

In this regard, reference may also be made to patent application EP 24177019.7 of May 21, 2024, in the name of the same Applicant, which describes a differential sensing scheme for a triaxial gyroscope that has substantially the same disturbance insensitivity features using the same movement scheme for the driving masses and for the sensing masses.

The advantages of the proposed solution are clear from the preceding description.

In any case, it is again emphasized that the described solution provides an optimized elastic coupling element for MEMS gyroscopes, which allows converting translational to rotational motion, with the following features: the direction of the movement of the driving mass is parallel to the rotation axis around which the sensing movement (of the sensing mass associated with the same driving mass) occurs; the sensitivity may be modified by simply shifting the coupling point between driving and sensing masses; and the frequency of the sensing mode may be easily adjusted by acting on geometric features of the elastic coupling element, with limited effect on the driving mode.

Furthermore, the described solution allows for the provision of a triaxial gyroscope, wherein: a single driving mode (at a single frequency) is used, since all sensing masses are directly coupled to the same driving masses (not being coupled to each other); the interferences between the sensing axes are substantially zero, since the sensing movement associated with each sensing axis is completely independent of the other sensing axes; both linear vibrations that cause interference and angular vibrations that cause interference are rejected in a substantially complete manner.

As a consequence of the above features, the coupling solution allows higher sensing accuracy to be obtained and, consequently, allows more efficient and quicker calibration operations.

Furthermore, the triaxial gyroscope has a compact architecture and does not require any substantial modification to the manufacturing process, in particular, without requiring additional processing steps or different treatments with respect to standard solutions.

Finally, it is clear that modifications and variations may be made to what has been described and illustrated herein without thereby departing from the scope of the present invention, as defined in the attached claims.

In particular, the elastic coupling solution previously described, for transferring the translational motion of a driving mass to the rotational motion of the associated sensing mass, may also find advantageous application in sensing structures of uniaxial or biaxial MEMS gyroscopes.

1. A MEMS gyroscope comprising a microelectromechanical structure having a main extension in a horizontal plane formed by a first horizontal axis and a second horizontal axis and including:
a first driving mass configured to perform a translation driving movement along the second horizontal axis of the horizontal plane; and
a first sensing mass, having an anchoring element, arranged centrally with respect to the first sensing mass, and connected to said anchoring element by an elastic arrangement;
wherein said first sensing mass is coupled to the first driving mass by an elastic coupling element and is configured to:
perform a rotation movement in said horizontal plane around the anchoring element, wherein said rotation movement is driven by said first driving mass; and
perform a sensing movement of rotation outside said horizontal plane around a rotation axis defined by said elastic arrangement, in response to a first angular velocity around the first horizontal axis;
wherein that said rotation axis extends along said second horizontal axis parallel to said translation driving movement of the first driving mass.

2. The MEMS gyroscope according to claim 1, wherein said elastic coupling element comprises:
a central portion linear along a direction of the second horizontal axis and rigid so as to transfer the translation driving movement of the first driving mass to the first sensing mass; and
end portions, arranged at distal ends of the central portion, respectively coupled to the first driving mass and to the first sensing mass;
wherein said end portions are elastic and yielding to allow rotation outside the horizontal plane of the first sensing mass.

3. The MEMS gyroscope according to claim 2, wherein said first sensing mass has an extension along said first horizontal axis symmetrical with respect to said rotation axis; and wherein said elastic coupling element is coupled to said first sensing mass at a coupling point arranged at a non-zero distance from said rotation axis along said first horizontal axis.

4. The MEMS gyroscope according to claim 3, wherein said central portion of said elastic coupling element has a length along said second horizontal axis and said end portions of said elastic coupling element have a folded shape, with an overall extension along the first horizontal axis and with a thickness of branches forming the folded shape; wherein a value of said non-zero distance determines a detection sensitivity of said first sensing mass and a value of said length of the central portion and of said overall extension and of said thickness of the end portions determines a frequency of said sensing movement.

5. The MEMS gyroscope according to claim 1, wherein said first sensing mass has a central window within which said anchoring element is arranged in a central position; said elastic arrangement also being arranged in the central window and having a main extension along said second horizontal axis and defining said rotation axis.

6. The MEMS gyroscope according to claim 1, wherein said microelectromechanical structure has a first axis of symmetry and a second axis of symmetry extending respectively along the first horizontal axis and along the second horizontal axis and comprises:
a second driving mass, in addition to said first driving mass, to thereby form a first pair of driving masses arranged on a same side of the second axis of symmetry and aligned along the second horizontal axis; and
a third driving mass and a fourth driving mass, that form a second pair of driving masses, arranged in a symmetrical manner to the first pair of driving masses with respect to the second axis of symmetry and aligned along the second horizontal axis;
a second pitch sensing mass, in addition to said first sensing mass, that represents a first pitch sensing mass for sensing a pitch angular velocity around the first horizontal axis, to form a pair of pitch sensing masses arranged in a symmetrical manner with respect to the first axis of symmetry, externally with respect to all of the driving masses of the first pair and of the second pair;
wherein said first pitch sensing mass is elastically coupled also to the third driving mass through a respective elastic coupling element, having features corresponding to said elastic coupling element, and said second pitch sensing mass is elastically coupled to both the second driving mass and the fourth driving mass through respective elastic coupling elements, having features corresponding to said elastic coupling element;
a first roll sensing mass and a second roll sensing mass for sensing a roll angular velocity around the second horizontal axis, arranged symmetrically to each other on opposite sides of the first axis of symmetry and elastically connected to each other by an elastic coupling element, arranged centrally at the second axis of symmetry, said first roll sensing mass and second roll sensing mass being arranged internally with respect to all of the driving masses of the first and second pairs, and wherein said first roll sensing mass is elastically coupled to the first and third driving masses, by respective elastic coupling elements, aligned along the first horizontal axis and said second roll sensing mass is elastically coupled to the second and fourth driving masses, by respective elastic coupling elements, aligned along the first horizontal axis;
a first pair of yaw sensing masses and a second pair of yaw sensing masses configured to sense a yaw angular velocity around a vertical axis orthogonal to said horizontal plane, arranged externally and coupled to the first and second pairs of driving masses by respective elastic coupling elements,
wherein said pitch sensing masses, said first roll sensing mass, said second roll sensing mass, said first pair of yaw sensing masses, and said second pair of yaw sensing masses are driven by all of the driving masses of the first and second pairs, with a common driving mode, in order to perform the respective sensing movements for detection of the pitch, roll and yaw angular velocities.

7. The MEMS gyroscope according to claim 6,
wherein the first, second, third, and fourth driving masses are configured to perform a translation movement, in phase-opposition for each pair, along the second horizontal axis, the translation movement of the first, second, third, and fourth driving masses symmetrical to each other with respect to the first axis of symmetry also being in phase-opposition; and
wherein the translation movement of the driving masses is configured to cause:
a rotation in phase-opposition of the first roll sensing mass and the second roll sensing mass in the horizontal plane, around an axis parallel to the vertical axis and passing through a respective center of the first roll sensing mass and the second roll sensing mass;
a translation movement in phase-opposition along the second horizontal axis of the first pair of yaw sensing masses and second pair of yaw sensing masses in a manner integral with the first, second, third, and fourth driving masses; and
a rotation in phase-opposition of the pitch sensing masses, around an axis parallel to the vertical axis and passing through a respective center of the pitch sensing masses.

8. The MEMS gyroscope according to claim 7, wherein movements of the first roll sensing mass, second roll sensing mass, first pair of yaw sensing masses, second pair of yaw sensing masses, and pitch sensing masses due to the translation movement of the first, second, third, and fourth driving masses occur entirely in the horizontal plane.

9. The MEMS gyroscope according to claim 7, wherein the sensing movements of the first roll sensing mass, second roll sensing mass, first pair of yaw sensing masses, second pair of yaw sensing masses, and pitch sensing masses are independent of each other and do not have any mutual influences.

10. The MEMS gyroscope according to claim 7, wherein the first, second, third, and fourth driving masses operate as decoupling elements between the first roll sensing mass, the second roll sensing mass, the first pair of yaw sensing masses, the second pair of yaw sensing masses, and the pitch sensing masses, which are all connected to the first driving mass, without mutual connections.

11. The MEMS gyroscope according to claim 7, wherein the pitch sensing masses are configured to perform, in presence of the pitch angular velocity around the first horizontal axis and due to Coriolis force, respective rotation movements outside the horizontal plane, in phase-opposition with each other, around the respective rotation axis defined by a respective elastic arrangement for coupling to a respective anchoring element.

12. The MEMS gyroscope according to claim 7, wherein the first roll sensing mass and the second roll sensing mass are configured to perform, in presence of the roll angular velocity around the second horizontal axis and due to Coriolis force, a rotation in phase-opposition outside the horizontal plane around a respective rotation axis defined by corresponding elastic coupling elements.

13. The MEMS gyroscope according to claim 7, wherein the first pair of yaw sensing masses, the second pair of yaw sensing masses, in presence of a yaw angular velocity around the vertical axis and due to Coriolis force, are configured to carry out a translation movement in phase-opposition along the first horizontal axis.

14. The MEMS gyroscope according to claim 6, wherein each of the first roll sensing mass and the second roll sensing mass has a substantially rectangular shape in the horizontal plane, elongated along the second horizontal axis and centrally has a window, inside of which a respective roll anchor is arranged, to which it is coupled by an elastic coupling arrangement defining a rotation axis for the sensing movement outside the horizontal plane.

15. The MEMS gyroscope according to claim 6,
wherein the yaw sensing masses and the first pair of yaw sensing masses and the yaw sensing masses of the second pair of yaw sensing masses are coupled to each other by respective elastic coupling structures, which extend centrally along the second horizontal axis, traversing the first axis of symmetry; and
wherein each elastic coupling structure defines a lever elastic element, of a central fulcrum type, hinged at a central anchor and coupled at its ends to the respective yaw sensing masses of the first or the second pair.

16. A method of operating a MEMS gyroscope comprising a microelectromechanical structure having first, second, third, and fourth driving masses, first and second pitch sensing masses, first and second roll sensing masses, and first and second pairs of yaw sensing masses, the method comprising:
driving the first, second, third, and fourth driving masses to perform translational movements in phase-opposition for each pair along a second horizontal axis, wherein the translational movements of the first, second, third, and fourth driving masses symmetrical to each other with respect to a first axis of symmetry are also in phase-opposition;
causing, due to the translational movements of the first, second, third, and fourth driving masses:
a rotation in phase-opposition of the first and second roll sensing masses in a horizontal plane around respective axes parallel to a vertical axis;
a translational movement in phase-opposition of the first and second pairs of yaw sensing masses along the second horizontal axis; and
a rotation in phase-opposition of the first and second pitch sensing masses around respective axes parallel to the vertical axis;
detecting a pitch angular velocity around the first horizontal axis by sensing rotation movements of the first and second pitch sensing masses outside the horizontal plane around respective rotation axes parallel to the second horizontal axis;
detecting a roll angular velocity around the second horizontal axis by sensing rotation movements of the first and second roll sensing masses outside the horizontal plane; and
detecting a yaw angular velocity around the vertical axis by sensing displacement movements of the first and second pairs of yaw sensing masses along the first horizontal axis.

17. The method of claim 16, wherein driving the first, second, third, and fourth driving masses comprises applying electrical signals to mobile driving electrodes integral with the driving masses and interdigitated with corresponding fixed driving electrodes arranged within windows of the driving masses.

18. The method of claim 16, wherein detecting the pitch angular velocity comprises capacitively sensing movement of the first and second pitch sensing masses away from and towards respective pitch stator electrodes using a differential sensing scheme.

19. The method of claim 16, wherein detecting the yaw angular velocity comprises capacitively sensing movement of yaw mobile sensing electrodes integral with the first and second pairs of yaw sensing masses with respect to alternating yaw stator sensing electrodes using a differential sensing scheme.

20. The method of claim 16, wherein the translational movements of the first, second, third, and fourth driving masses and the resulting movements of the first and second pitch sensing masses, the first and second roll sensing masses, and the first and second pairs of yaw sensing masses occur entirely in the horizontal plane, and wherein the sensing movements for detecting the pitch, roll, and yaw angular velocities are independent of each other without mutual influences.
